(19) United States
(12) Patent Application Publication
(10) Pub. No.: US 2007/0063303 A1
(43) Pub. Date: Mar. 22, 2007

(54) CMOS image sensor and method for manufacturing the same

(76) Inventor: Keun Hyuk Lim, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/525,664

(22) Filed: Sep. 22, 2006

(30) Foreign Application Priority Data
Sep. 22, 2005 (KR) 10-2005-0088192

(51) Int. Cl. H01L 31/06

(52) U.S. Cl. 257/461; 257/E31.01

(57) ABSTRACT

Provided are a CMOS image sensor and a manufacturing method thereof. The CMOS image sensor includes a gate insulating layer and a gate electrode, a low-density diffusion region of a second conductive type, a high-density diffusion region of the second conductive type, and a high-density diffusion region of a first conductive type. The gate insulating layer and a gate electrode are sequentially formed on an active region of a substrate of the first conductive type having a photodiode region and a transistor region. The low-density diffusion region of the second conductive type is formed on the photodiode region. The high-density diffusion region of the second conductive type is formed on the transistor region. The high-density diffusion region of the first conductive type is formed on the transistor region to nestle the high-density diffusion region of the second conductive type.

### RELATED APPLICATION

This application claims the benefit under 35 U.S.C. §119(e), of Korean Patent Application Number 10-2005-0088192 filed Sep. 22, 2005, which is incorporated herein by reference in its entirety.

### FIELD OF THE INVENTION

The present invention relates to a CMOS image sensor and a method of manufacturing the same.

### BACKGROUND OF THE INVENTION

In general, an image sensor is a semiconductor device that converts an optical image to an electrical signal. Image sensors can largely be divided into charge coupled devices (CCD) and complementary metal oxide silicon (CMOS) image sensors.

A CCD image sensor has a complex driving method, consumes much power, and requires multiple photo processing stages, so that manufacture thereof is complicated. Therefore, the CMOS image sensor is being favored as the next generation image sensor to overcome the problems associated with the CCD image sensor.

A CMOS image sensor includes a photodiode and a metal oxide silicon (MOS) transistor in a unit pixel, and sequentially detects the electrical signals of each unit pixel through a switching method to form an image.

CMOS image sensors, depending on their numbers of transistors, are classified as 3T-type, 4T-type, 5T-type, and so forth. A 3T-type has one photodiode and 3 transistors, and a 4T-type has one photodiode and 4 transistors.

The CMOS image sensor according to the related art shown in FIG. 1, for example, is a 4T-type CMOS image sensor that has a low density P type epitaxial layer (epilayer) 62 on which a transfer gate 65 is defined, and in which an N-implant is performed for the photodiode (PD) 67.

When the N+ region of drain 69 becomes a floating diffusion (FD), the transfer transistor is turned on and light causes the electrons in the PD 67 to be transferred and stored in the FD 69. However, the low density of the N− PD 67 and the low density of the epilayer 62 cause a depletion region A to be expansively formed. A depletion region is also formed between the epilayer 62 and the FD 69, so that the two depletion regions come into contact with one another, and the electrons, generated by light, flow out through the connection.

That is, according to the related art, a PD 67 is formed on a P-type epilayer 62. To form the PD 67, the N− implant is doped at low density and the P-type epilayer is doped at low density, so that a wide depletion layer A is formed. As a result, there is a high probability that a punch effect will occur on a drain FD 69 of a transfer gate. If the punch effect occurs, the resulting leakage will cause a loss of electrons generated by light through the PD 67, thereby compromising the operating characteristics of the CMOS image sensor.

### SUMMARY OF THE INVENTION

Accordingly, the present invention is directed to a CMOS image sensor and a manufacturing method thereof that addresses and/or substantially obviates one or more problems, limitations, and/or disadvantages of the related art.

An object of the present invention is to provide a CMOS image sensor with improved operating characteristics brought about by eliminating a punch effect through the forming of a P⁺ type impurity region to surround a floating diffusion region in the form of a pocket or nest, and a manufacturing method for the CMOS image sensor.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a CMOS image sensor including: a gate insulating layer and a gate electrode sequentially formed on an active region of a substrate of a first conductive type having a photodiode region and a transistor region; a low-density diffusion region of a second conductive type formed on the photodiode region; a high-density diffusion region of the second conductive type formed on the transistor region; and a high-density diffusion region of the first conductive type formed on the transistor region to nestle the high-density diffusion region of the second conductive type from below.

In another aspect of the present invention, there is provided a method of fabricating a CMOS image sensor, including: forming a gate insulating layer and a gate electrode sequentially on an active region of a substrate of a first conductive type having a photodiode region and a transistor region; forming a low-density diffusion region of a second conductive type on the photodiode region; forming a high-density diffusion region of the first conductive type in the substrate through ion implantation of a first impurity type at a high density in the transistor region; and forming a high-density diffusion region of the second conductive type in the substrate through ion implantation of a second impurity type at a high density in the transistor region such that the high-density diffusion region of the second conductive type is nestled by the high-density diffusion region of the first conductive type from below.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view of a CMOS image sensor according to the related art;

FIG. 2 is a sectional view of a CMOS image sensor according to an embodiment of the present invention; and

FIGS. 3 through 7 are sectional views showing the different manufacturing stages of a CMOS image sensor according to an embodiment of the present invention.

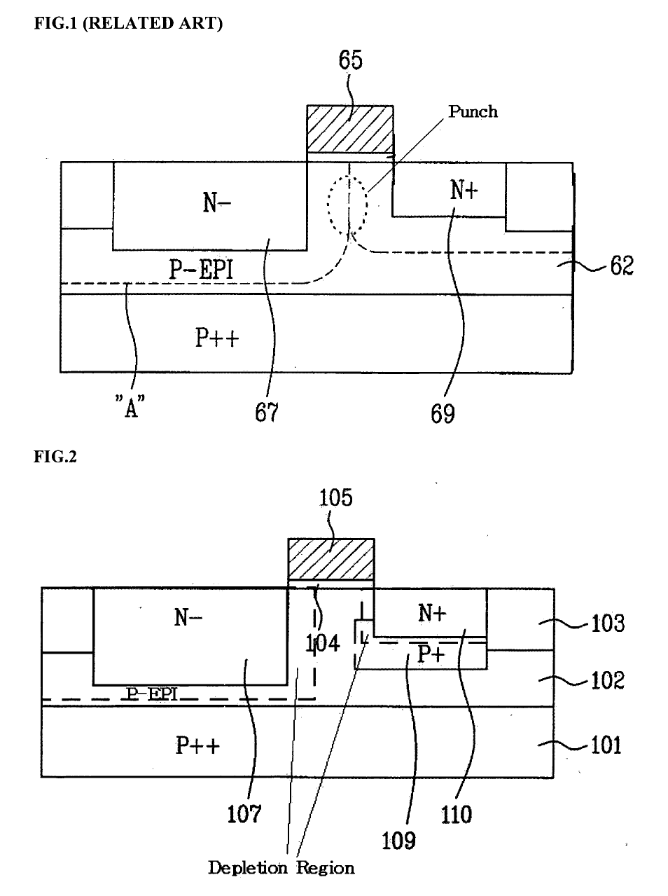

### DETAILED DESCRIPTION OF THE INVENTION

Reference will now be made in detail to a CMOS image sensor and a method for manufacturing the same, according to preferred embodiments of the present invention, examples of which are illustrated in the accompanying drawings. Wherever possible, the same reference numbers will be used throughout the drawings to refer to the same or like parts.

While a 4T CMOS image sensor is exemplarily used to describe the present invention, the present invention is not limited thereto, and may apply equally to a 3T CMOS image sensor, a 5T CMOS image sensor, etc.

FIG. 2 is a sectional view of a CMOS image sensor according to an embodiment of the present invention.

Referring to FIG. 2, a p⁺⁺ conductive type semiconductor substrate 101 can have a p⁻ type epilayer 102 formed thereon. A device isolation layer 103 can be formed on a field region to define an active region of the semiconductor substrate 101, which can include a photodiode region and a transistor region.

A gate insulating layer 104 can be formed on the active region of the semiconductor substrate 101, and a gate electrode 105 can be formed thereon.

A low-density n⁻ type diffusion region 107 can be formed on the photodiode region at one side of the gate electrode 105, and a high-density n⁺ type diffusion region 110 can be formed on the transistor region on the other side of the gate electrode 105.

Also, a high-density p⁺ type diffusion region 109 can be formed to nestle the high-density n⁺ type diffusion region 110 of the transistor region. The high-density p⁺ type diffusion region 109 can be formed through ion implantation at a higher dose than that of the low-density n⁻ type diffusion region 107.

That is, in the CMOS image sensor according to an embodiment of the present invention, the p⁺ type diffusion region 109 is formed to nestle the high density n⁺ type diffusion region 110 at a bottom thereof, so that when the n⁻ region of the photodiode has the effect of forming a wide depletion region, the expansive formation of the depletion region can be reduced because the p⁺ diffusion region has a density higher than the epilayer in the middle and lower portions of the floating diffusion region. As a result, a punch effect can be effectively prevented.

In a CMOS image sensor according to an embodiment of the present invention, the high-density p⁺ type diffusion region 109 can be formed to a depth closer to the surface of the substrate than the low-density n⁻ type diffusion region 107. Therefore, the high-density p⁺ type diffusion region 109 can effectively block the diffusion of the low-density n⁻ type diffusion region 107, preventing a punch effect.

In a specific embodiment, the high-density p⁺ type diffusion region 109 may be formed to a recessed level of about 0.25 μm from the surface of the substrate, and the low-density n⁻ type diffusion region 107 may be formed to a recessed level of about 0.5 μm from the surface of the substrate.

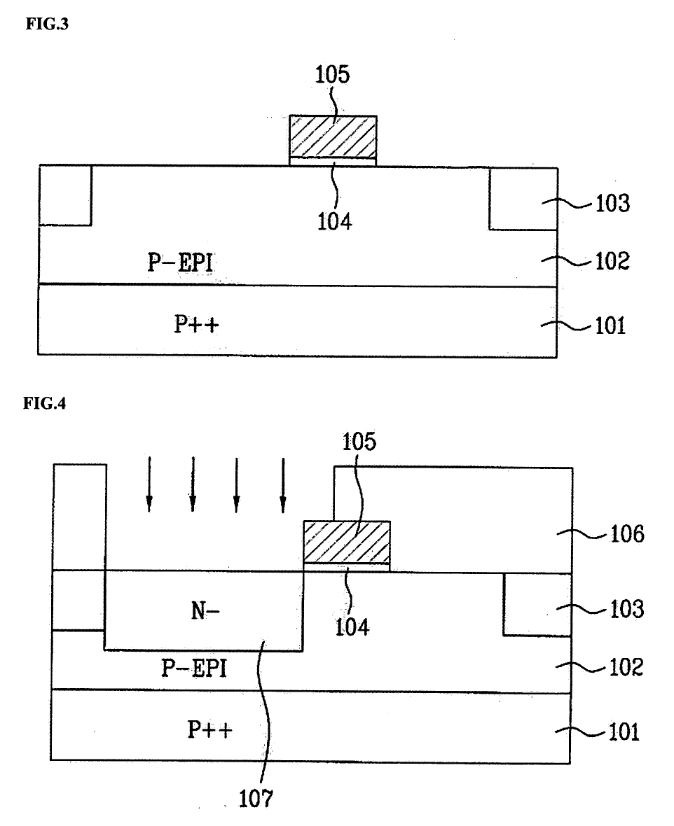

FIGS. 3 through 7 are sectional views showing the different manufacturing stages of a CMOS image sensor according to an embodiment of the present invention.

Referring to FIG. 3, in one embodiment, a first conductive p⁻ type epilayer 102 can be formed through an epitaxial process on a semiconductor substrate 101 of a first conductive p⁺⁺ type single crystal silicon.

Here, the epilayer 102 can form an expansive and deep depletion region on the photodiode, in order to increase the capacity of a low voltage photodiode that focuses light beam transmission and to improve light sensitivity.

In another embodiment, the semiconductor substrate 101 may be formed as a p-type epilayer on an n-type substrate.

A device isolation layer 103 can be formed on the semiconductor substrate 101 including the epilayer 102, to secure spaces between devices. In embodiments, the device isolation layer 103 may be formed through a local oxidation of silicon (LOCOS) process or a shallow trench isolation (STI) process.

Then, a gate insulating layer 104 and a conductive layer (for example, a high density polycrystal silicon layer) can be sequentially deposited on the entire surface of the epilayer 102, including the device isolation layer 103.

In a specific embodiment, a gate insulating layer 104 can be formed through a heat oxidation process or through a CVD method. Then, the conductive layer and the gate insulating layer can be selectively removed to form a gate electrode 105. Here, the gate electrode 105, as shown in FIGS. 3-7, is a gate electrode of a transfer transistor.

Next, referring to FIG. 4, a first photosensitive layer 106 can be formed on the entire surface of the semiconductor substrate 101 including the gate electrode 105. Then, the first photosensitive layer 106 can be selectively patterned through an exposing and developing process to expose each photodiode region.

Next, a low-density n⁻ type diffusion region 107 can be formed by implantation of n⁻ type impurity ions at a low density on the photodiode regions using the first photosensitive layer 106 as a mask. In a specific embodiment, the low-density n⁻ type diffusion region 107 may be formed to a depth of about 0.5 cm or less.

Next, with reference to FIG. 5, after the first photosensitive layer 106 is removed, a second photosensitive layer 108 can be formed on the entire surface of the semiconductor substrate 101. Then the second photosensitive layer 106 can be patterned to expose each transistor source/drain region through an exposing and developing process.

The patterned second photosensitive layer 108 can be used as a mask, and p⁺ type impurity ions can be implanted at a high density in the exposed source/drain regions to form a high-density p⁺ type diffusion region 109 in the semiconductor substrate 101.

In a specific embodiment, the implanted high-density p⁺ type impurity ions may be boron (B) or BF₂ ions.

In one embodiment, the high-density p⁺ type diffusion region 109 can be implanted with ions with about 100-160 KeV of energy, so that the high-density p⁺ type diffusion region 109 surrounds a high-density n⁺ type diffusion region 110 (to be formed in an upcoming stage) from below resulting in a pocket or nest.

The high-density p⁺ type diffusion region 109 can have a higher dose of ions implanted therein than the low-density n− type diffusion region 107. In an embodiment, the high-density p⁺ type diffusion region 109 can have an ion implantation dose of 5×10¹³−1×10¹⁴.

In one embodiment, the high-density p⁺ type diffusion region 109 may have an ion implantation dose of 1×10¹⁴ implanted at a 130 KeV level of energy.

That is, in the CMOS image sensor according to the present invention, the p⁺ type diffusion region 109 can be formed to nestle a high density n⁺ type diffusion region 110 at a bottom thereof, so that when the n⁻ type region of the photodiode has the effect of forming a wide depletion region, the expansive formation of the depletion region can be reduced because the p⁺ diffusion region has a density higher than the epilayer in the middle and lower portions of the floating diffusion region. As a result, a punch effect can be effectively prevented.

The high-density p⁺ type diffusion region 109 can be formed less deeply into the substrate than the low-density n⁻ type diffusion region 107, so that the high-density p⁺ type diffusion region 109 can effectively block depletion of the n⁻ type diffusion region 107, preventing a punch effect.

In one embodiment example, the high-density p⁺ type diffusion region 109 can be implanted with ions at an energy of about 100-160 KeV and formed to a depth of about 0.25 μm or less into the surface of the substrate, and the low-density n⁻ type diffusion region 107 may be formed to a depth of about 0.5 μm or less into the surface of the substrate.

In a further embodiment, the high-density p⁺ type diffusion region 109 can be formed to extend to a lower end of the gate electrode 105 in order to prevent a punch effect.

For this embodiment, in order to form the high-density p⁺ type diffusion region 109, an angle for ion implantation can be tilted so that the high-density p⁺ type diffusion region 109 can be extended to one end of the gate electrode 105.

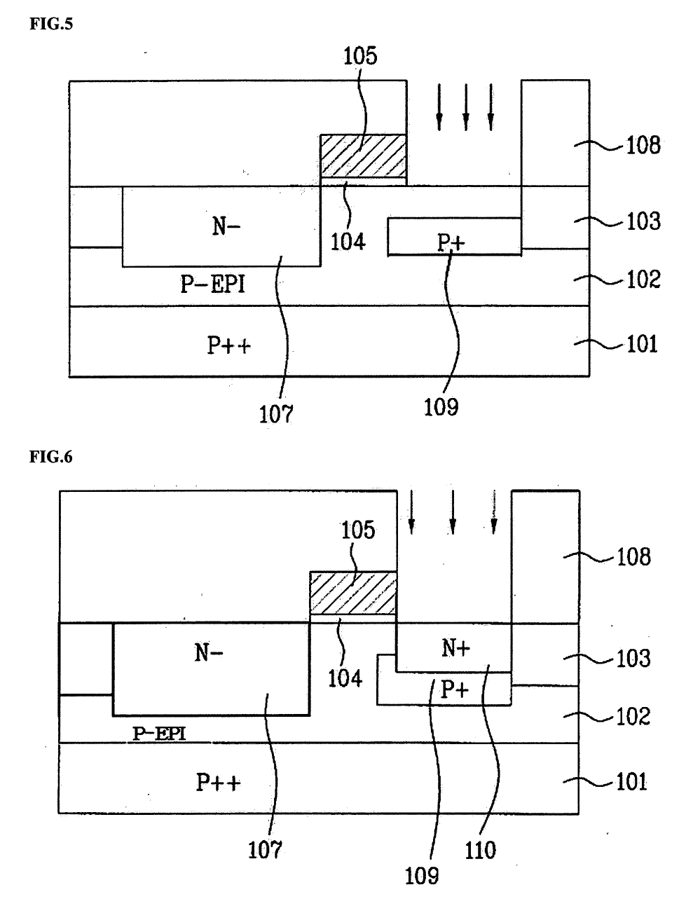

Next, as shown in FIG. 6, the patterned second photosensitive layer 108 can also be used as a mask to perform implantation of n⁺ type impurity ions at a high density in the exposed source/drain regions to form a high-density n⁺ type diffusion region (floating diffusion region) 110 in the semiconductor substrate 101. Here, the ion implantation may be performed perpendicularly to the semiconductor substrate in order to form the high-density n+ type diffusion region 110.

Accordingly, in embodiments, the high-density p⁺ type diffusion region 109 surrounds the high-density n⁺ type diffusion region 110 from below in the form of a pocket or nest.

In a specific embodiment, the high-density n⁺ type impurity ions may be As ions implanted at an energy of about about 60-90 KeV at a dosage of 1×10¹⁵−1×10¹⁶, so that the high-density p⁺ type diffusion region 109 nestles the high-density n⁺ type diffusion region 110 from below.

In one embodiment example, the high-density n⁺ type impurity ions may be As ions implanted at an energy of 80 KeV at a dosage of 4×10¹⁵.

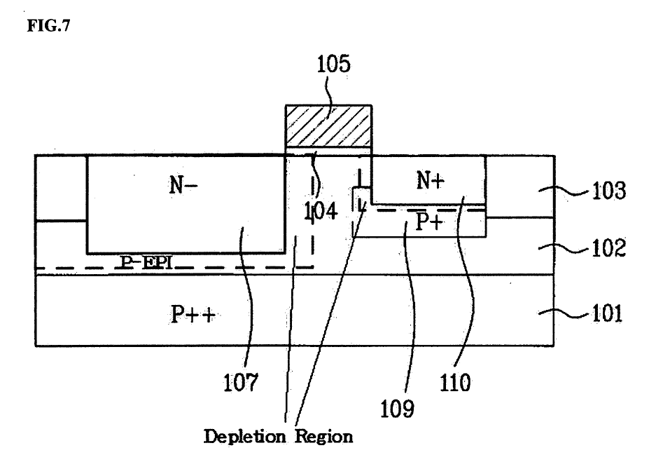

Next, as shown in FIG. 7, the second photosensitive layer 108 is removed, and the semiconductor substrate 101 can be subjected to a heat treatment process (e.g., rapid heat treating) to diffuse the impurity ions within the n⁻ type diffusion region 107 and the n⁺ type diffusion region 110.

The above-described CMOS image sensor according to the present invention has the following benefits.

By forming the high-density p⁺ type diffusion region to nestle the floating diffusion region at a bottom thereof, when the n⁻ region of the photodiode has the effect of forming a wide depletion region, which affects the floating diffusion region, the expanding effect of a depletion region is reduced through a p-type diffusion region with a higher density than the epilayer in the middle and lower portions of the floating diffusion region, preventing a punch effect as a result.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CMOS (complementary metal oxide semiconductor) image sensor comprising:
a gate insulating layer and a gate electrode sequentially formed on an active region of a substrate of a first conductive type having a photodiode region and a transistor region;
a low-density diffusion region of a second conductive type formed on the photodiode region;
a high-density diffusion region of the second conductive type formed on the transistor region; and
a high-density diffusion region of the first conductive type formed on the transistor region to nestle the high-density diffusion region of the second conductive type.

2. The CMOS image sensor according to claim 1, wherein the high-density diffusion region of the first conductive type nestles the high-density diffusion region of the second conductive type from therebelow.

3. The CMOS image sensor according to claim 1, wherein the high-density diffusion region of the first conductive type is formed less deeply into the substrate than the low-density diffusion region of the second conductive type.

4. The CMOS image sensor according to claim 3, wherein the high-density diffusion region of the first conductive type is formed to a depth of 0.25 μm or less from a surface of the substrate.

5. The CMOS image sensor according to claim 3, wherein the low-density diffusion region of the second conductive type is formed to a depth of about 0.5 μm or less from a surface of the substrate.

6. The CMOS image sensor according to claim 1, wherein the high-density diffusion region of the first conductive type is formed to extend to below a lower edge of the gate electrode.

7. The CMOS image sensor according to claim 1, wherein the high-density diffusion region of the first conductive type is formed with a higher ion implantation dose than the low-density diffusion region of the second conductive type.

8. A method of fabricating a CMOS image sensor, the method comprising:
forming a gate insulating layer and a gate electrode sequentially on an active region of a substrate of a first conductive type having a photodiode region and a transistor region;
forming a low-density diffusion region of a second conductive type on the photodiode region;
forming a high-density diffusion region of the first conductive type in the transistor region by implanting first type impurity ions at a high density into the substrate; and
forming a high-density diffusion region of the second conductive type in the transistor region by implanting second type impurity ions at a high density into the substrate such that the high-density diffusion region of the first conductive type nestles the high-density diffusion region of the second conductive type.

9. The method according to claim 8, wherein the high-density diffusion region of the first conductive type nestles the high-density diffusion region of the second conductive type from therebelow.

10. The method according to claim 9, wherein the first type impurity ions are implanted into the substrate at an energy level of from about 100 to 160 KeV.

11. The method according to claim 9, wherein the second type impurity ions are implanted into the substrate at an energy level of from about 60 and 90 KeV.

12. The method according to claim 8, wherein the high-density diffusion region of the first conductive type is formed with a higher ion implantation dose than the low-density diffusion region of the second conductive type.

13. The method according to claim 12, wherein the high-density diffusion region of the first conductive type is formed with an ion implantation dose of from 5×10¹³ to 1×10¹⁵.

14. The method according to claim 13, wherein the first type impurity ions implanted at a high density into the substrate are B (boron) ions.

15. The method according to claim 13, wherein the first type impurity ions implanted at a high density into the substrate are BF₂ ions.

16. The method according to claim 8, wherein the high-density diffusion region of the second conductive type is formed with an ion implantation dose of from 1×10¹⁵ to 1×10¹⁶.

17. The method according to claim 8, wherein the high-density diffusion region of the first conductive type is formed to extend below a lower edge of the gate electrode.

18. The method according to claim 8, wherein the high-density diffusion region of the first conductive type is formed less deeply into the substrate than the low-density diffusion region of the second conductive type.

19. The method according to claim 18, wherein the high-density diffusion region of the first conductive type is formed to a depth of 0.25 μm or less from a surface of the substrate by implanting the first type impurity ions at an energy level of from about 100 to 160 KeV to be.

20. The method according to claim 18, wherein the low-density diffusion region of the second conductive type is formed to a depth of about 0.5 μm or less from a surface of the substrate.
